(19) United States
(12) Patent Application Publication
(10) Pub. No.: US 2025/0118527 A1
(43) Pub. Date: Apr. 10, 2025

(54) PARTICLE BEAM SYSTEM WITH COOLING SYSTEM

(71) Applicant: Carl Zeiss Microscopy GmbH, Jena (DE)

(72) Inventor: Andreas Schmaunz, Oberkochen (DE)

(21) Appl. No.: 18/910,644

(22) Filed: Oct. 9, 2024

(30) Foreign Application Priority Data
Oct. 10, 2023 (DE) 10 2023 127 667.0

(51) Int. Cl. H01J 37/20

(52) U.S. Cl. CPC H01J 37/20; H01J 2237/002

(57) ABSTRACT

A particle beam system comprises: an object mount for mounting an object to be examined; a particle beam source for creating a particle beam; a lens for focusing the particle beam on the object; a detector for detecting signals created at the object by the particle beam; a cooling system configured to provide a flow of a coolant through a coolant passage through the object mount; and a controller. The cooling system comprises: a cooling mechanism configured to cool the flow of the coolant in a coolant passage through the cooling mechanism; and a pump configured to convey the coolant in order to create the flow of the coolant.

### CROSS-REFERENCE TO RELATED APPLICATION

This application claims benefit under 35 U.S.C. § 119 to German Application No. 10 2023 127 667.0, filed Oct. 10, 2023. The entire disclosure of this application is incorporated by reference herein.

### FIELD

The present disclosure relates to a particle beam system having a cooling system and to a method of operating such a particle beam system.

### BACKGROUND

In some cases, the examination of microscopic structures of an object comprises recording particle-optical images by virtue of using a particle beam system that scans a region on the object using a particle beam. There is a desire to keep a temperature of the object low for the purpose of recording the particle-optical image, especially in the case of biological and chemical objects. In this regard, use is usually made of an object mount for mounting the object in the particle beam system, the object mount being connected to a nitrogen cooling mechanism. For example, an object mount of this type is available under the product name “PP3006 CoolLok” or “PP3005 SEMCool” from Quorum Technologies Ltd, Laughton, United Kingdom.

In such nitrogen cooling solutions, gaseous nitrogen is usually supplied at overpressure, on account of which the nitrogen flows through the cooling system. Then, after flowing through the cooling system, the nitrogen reaches the surroundings. Accordingly, a user of the particle beam system regularly purchases new nitrogen; this results in increased costs and more outlay for the user of the particle beam system.

### SUMMARY

The present disclosure seeks to reduce nitrogen consumption and hence reduce such additional outlay for the user.

A particle beam system is proposed, comprising an object mount for mounting an object to be examined, a particle beam source for creating a particle beam, a lens for focusing the particle beam on the object, and a detector for detecting signals created at the object by the particle beam. The particle beam system also comprises a cooling system configured to provide a flow of coolant through a coolant passage through the object mount, and a controller. In this context, the cooling system comprises a cooling mechanism configured to cool the flow of the coolant in a coolant passage through the cooling mechanism and a pump configured to convey the coolant in order to create the flow of the coolant. In this context, the pump is an apparatus that can be driven in order to create a flow of the coolant in the cooling system.

For example, the coolant is gaseous nitrogen. In the described particle beam system, the flow of nitrogen is created by the pump rather than the overpressure. It is therefore possible to convey the nitrogen in a closed circuit, for example, from which only a small amount of nitrogen can escape. Nitrogen is sucked in by the pump and discharged in such a way that the nitrogen circulates in a circuit comprising the coolant passage through the cooling mechanism and the coolant passage through the object mount. Hence, the nitrogen need not be discharged into the surroundings, and nitrogen consumption is reduced.

According to some embodiments, the pump is arranged such that coolant discharged by the pump flows first through the cooling mechanism and then through the object mount. This is desirable since cooled nitrogen can damage the pump in the long run. Since the cooled nitrogen is heated when flowing through the object mount, such damage to the pump becomes less likely. For example, the cooling system for heating the nitrogen can comprise a heat exchanger having a first passage and a second passage. In this case, the first passage through the heat exchanger is arranged in the flow of the nitrogen upstream of the cooling mechanism and downstream of the pump, and the second passage through the heat exchanger is arranged in the flow of the coolant upstream of the pump and downstream of the object mount. This means that heat exchange is performed between the nitrogen to be heated after flowing through the coolant passage through the object mount and the nitrogen to be cooled after flowing through the pump. Further apparatuses for heating the nitrogen, for instance a heating element, can be arranged in the flow of the nitrogen before the latter flows through the pump. In addition to heating the nitrogen following the latter's emergence from the coolant passage through the object mount, the heat exchanger also serves to pre-cool the nitrogen prior to its entrance into the coolant passage through the cooling mechanism. Should the cooling mechanism use liquid nitrogen to cool the nitrogen flowing through the coolant passage through the cooling mechanism, a consumption of nitrogen by the heat exchanger is further reduced since the liquid nitrogen absorbs a smaller quantity of heat from the gaseous nitrogen, and hence a smaller amount of the liquid nitrogen evaporates.

Since gaseous nitrogen compresses significantly in the event of cooling, it is further desirable for the cooling system to be designed such that this compression of the nitrogen has little to no influence on the cooling system. To this end, the cooling system according to some embodiments has a coolant-containing maximum volume that is at least 1000-times larger than a volume of all cooled sections of the cooling system. One or more compensation containers with a maximum overall volume 1000-times larger than the volume of all cooled sections of the cooling system can be provided to this end. For example, the volume of all cooled sections of the cooling system corresponds to a sum of the volume of the coolant passage through the object mount, the volume of the coolant passage through the cooling mechanism, and the volume of a coolant line connecting the coolant passage through the cooling mechanism to the coolant passage through the object mount. In such a case, a change in the volume of the nitrogen in the cooling system is small relative to an overall amount of nitrogen in the cooling system, whereby the change in volume can be negligible.

It should be observed that although the coolant line connects the coolant passage through the cooling mechanism to the coolant passage through the object mount, further functional components might be arranged in the flow of the coolant between the coolant passage through the cooling mechanism and the coolant passage through the object mount and might be arranged in the coolant line for example. For example, valves, sensors or the like might be provided in this coolant line. The same also applies to other coolant lines specified herein.

According to some embodiments, the compensation containers have an inlet opening for the coolant and an outlet opening for the coolant and provide a passage between the inlet opening and the outlet opening. That is to say, the coolant flows through the compensation containers in such embodiments. Alternatively, the compensation containers can be connected to the flow of the coolant, for example via a further coolant line, and can comprise a pressure valve such that an amount of coolant corresponding to the change in volume of the cooled coolant flows into the cooling system from the compensation containers. For example, at least one compensation container providing a passage for the coolant can be arranged in the flow of the coolant downstream of the object mount and upstream of the pump. This is desirable because in the event of a flow through the compensation container between the object mount and the pump, it is possible to provide a heating element on the compensation container, whereby the coolant can easily be heated.

According to some embodiments, at least one of the compensation containers has a variable volume for the coolant. For example, a compensation container can be connected to the cooling system via a further coolant line and can comprise a stretchable or flexible sleeve. Should the coolant in the cooling system be cooled and compressed, the stretchable or flexible sleeves contracts and reduces an overall volume in the cooling system, whereby a pressure in the cooling system can be kept constant. A change in volume of the coolant during cooling is compensated in this way.

According to some embodiments, the cooling system also comprises a reducing valve arranged in the flow of the coolant and providing a variable resistance to the flow of the coolant through the reducing valve, and a temperature sensor for outputting a signal that represents a temperature of the object mount. Moreover, the controller of the particle beam system is configured to control the reducing valve on the basis of the signal that represents the temperature of the object mount.

In this case, the reducing valve is a valve capable of setting an amount of coolant flowing through the cooling system. The reducing valve can be an electrically controllable valve, for example a magnetic valve that can be controlled by the controller for the purpose of setting a flow of the coolant. The temperature sensor is a sensor capable of measuring a temperature of the object mount and of communicating this temperature to the controller by way of an appropriate signal. This can be desirable for providing feedback control of the cooling system. For example, a target temperature for the object mount might be settable in such an embodiment. Then, the controller is capable of increasing a flow of coolant to such an extent that the temperature sensor detects the target temperature at the object mount, or detects the target temperature over a relatively long period of time, during which the object mount has reached a thermal equilibrium. Alternatively, the controller can also set the flow of the coolant by controlling the delivery rate of the pump, and so the reducing valve is not required for the purpose of setting the flow of the coolant. In this case, the delivery rate of the pump is a quantity that represents a flow of the coolant conveyed by the pump. For example, the delivery rate of the pump can be specified as a flow rate of the coolant.

According to some embodiments, the cooling system further comprises a pressure sensor for outputting a signal that represents a pressure of the coolant in the flow of the coolant downstream of the object mount and upstream of the cooling mechanism. Moreover, the controller is configured to control a delivery rate of the pump on the basis of the signal that represents the pressure. Such control of the delivery rate of the pump can be desirable since a pressure of the coolant in the cooling system can be kept constant. Thus, in a manner similar to what was described above in relation to the variable volume of the compensation containers, a change in volume of the coolant in the event of cooling can be compensated for by virtue of keeping a pressure of the coolant constant.

According to some embodiments, the cooling system further comprises a first portion of a coolant line which is arranged in the flow of the coolant downstream of the cooling mechanism and upstream of the object mount and which is surrounded by an insulating layer. The insulating layer reduces a heat transfer between the first portion of the coolant line and the surroundings. For example, a further coolant line connecting the pump e.g. to the first passage through the heat exchanger or the pump to the coolant passage through the cooling mechanism does not have this surrounding insulating layer. For example, the insulating layer is a cladding of the portion of the coolant line having a material which has a small coefficient of thermal conductivity. An insulating layer can also be realized by virtue of the coolant line connecting the coolant passage through the cooling mechanism to the coolant passage through the object mount being surrounded by a housing within which a vacuum is created. A vacuum also prevents the coolant line from icing over since the portion of the coolant line surrounded by the insulating layer does not come into contact with suspended water from the surroundings.

It may also be desirable for the insulating layer to also surround the heat exchanger and a further coolant line connecting the coolant passage through the object mount to the second passage through the heat exchanger. Since the coolant emerging from the coolant passage through the object mount in the case of such a heat exchanger should be used for cooling the coolant discharged from the pump, it is desirable to reduce heating of the coolant in the coolant line connecting the coolant passage through the object mount and the second passage through the heat exchanger. The insulating layer can also be realized by virtue of the aforementioned vacuum housing being connected to a vacuum chamber of the particle beam system.

According to some embodiments, the cooling mechanism comprises a cooling space. The cooling space is a volume into which a coolant, for example liquid nitrogen, can be filled. In this context, the coolant can be filled into the cooling space before a start of the cooling operation of the cooling system. For example, the cooling passage through the cooling mechanism is submersed in this liquid nitrogen during a cooling operation of the particle beam system and can be non-destructively removed from the liquid nitrogen when the cooling operation of the cooling system is terminated.

According to some embodiments, the particle beam system furthermore comprises a vacuum cladding which delimits a vacuum chamber. For example, the vacuum cladding is a metal housing of the particle beam system. A vacuum is created in the vacuum chamber during the operation of the particle beam system in order to reduce unwanted interactions of the particle beam with an atmosphere. In this context, it can be desirable for components whose operation does not require a vacuum to be arranged outside of the vacuum chamber since this can reduce an extent of the vacuum chamber and prevent a superfluous energy increase when creating the vacuum. For example, the cooling mechanism and/or the pump can be arranged outside of the vacuum chamber. Moreover, as described above, the insulating layer might be connected to the vacuum chamber such that a vacuum pump simultaneously creates the vacuum for scanning the object using the particle beam and the vacuum for insulating the first portion of the coolant line connecting the coolant passage through the cooling mechanism to the coolant passage through the object mount.

According to some embodiments, the particle beam system further comprises an object stage, which holds the object mount and for example is connected to an actuator which can be driven to displace the object mount-mounted object over the object stage relative to the lens for focusing the particle beam. For example, the object mount is held at a distance from the object stage by way of spacers in order to reduce the heat transfer between the object mount to be cooled and the object stage connected to the actuator. Fewer than ten and for example three spacers are used to maintain the distance between the object mount and the object stage. For example, the spacers are made of a material which has a low coefficient of thermal conductivity and are manufactured in spherical shape in order to minimize heat transfer from the object stage to the object mount. Alternatively, the object mount might for example not be carried by an object stage but be guided into the vacuum chamber through a vacuum lock on a connection. In this case, the vacuum lock is a feedthrough through the vacuum cladding with two seals, which close with a time offset from one another when the object mount is removed from the vacuum chamber such that the vacuum prevalent within the vacuum chamber can be maintained during the removal.

According to some embodiments, a method for operating the particle beam system comprises the following steps: pre-cooling the coolant in the first passage using the heat exchanger, cooling the coolant in the coolant passage through the cooling mechanism, using the cooled coolant to cool the object mount and an object arranged on the object mount, using the coolant in the second passage through the heat exchanger for pre-cooling using the heat exchanger after the object mount has been cooled, and scanning the particle beam over the object and detecting signals using the detector. This means that, proceeding from the pump of the cooling system, the coolant is initially pre-cooled when flowing through the first passage through the heat exchanger, whereupon the coolant flows through the coolant passage through the cooling mechanism, in which the coolant is cooled. The coolant then flows through the coolant passage through the object mount and cools the latter together with an object mounted thereon. After the coolant leaves the coolant passage through the object mount, the coolant flows through the second passage through the heat exchanger in order to pre-cool, by way of heat exchange, the coolant emerging from the pump. The coolant is sucked into the pump and emerges from the latter again in order to be pre-cooled in the first passage through the heat exchanger. The cooled object is scanned using the particle beam, and signals created by the object upon the incidence of the particle beam are captured by the detector, whereby a particle-optical image can be created.

The coolant that is fed is gaseous nitrogen according to some embodiments. In this case, it should be observed that gases usually contain contaminants. Herein, gases in which a proportion of the contaminants vis-à-vis a proportion of the actual nitrogen is low are referred to as gaseous nitrogen.

Specific embodiments will be explained in detail below on the basis of the figures, in which:

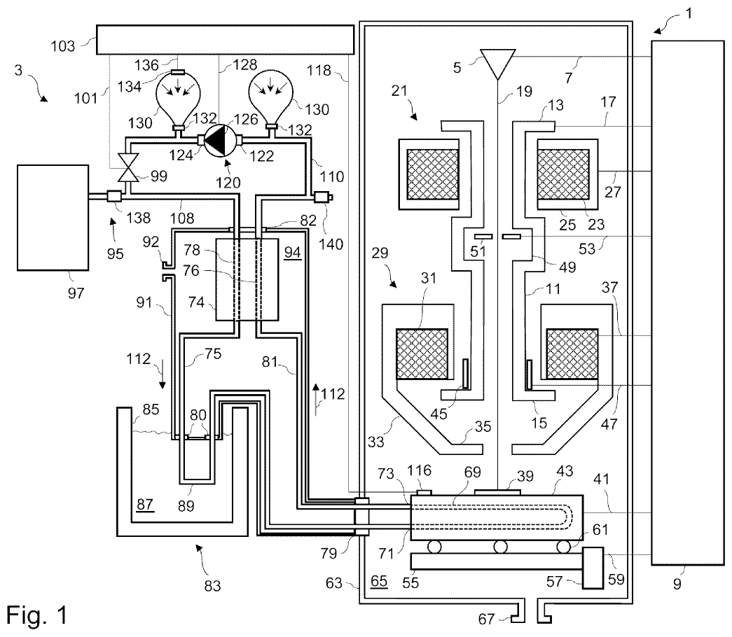

FIG. 1 shows a particle beam system having a cooling system according to one embodiment;

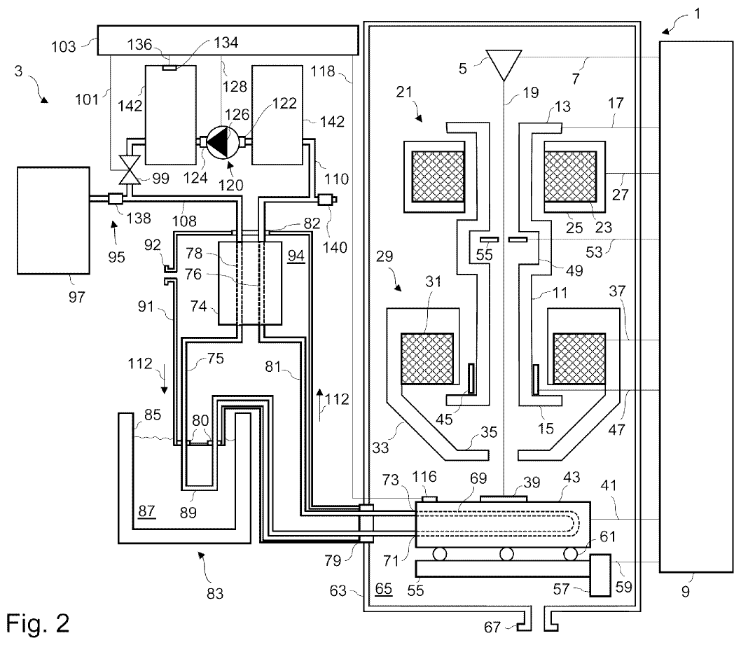

FIG. 2 shows a particle beam system having a cooling system according to a further embodiment; and

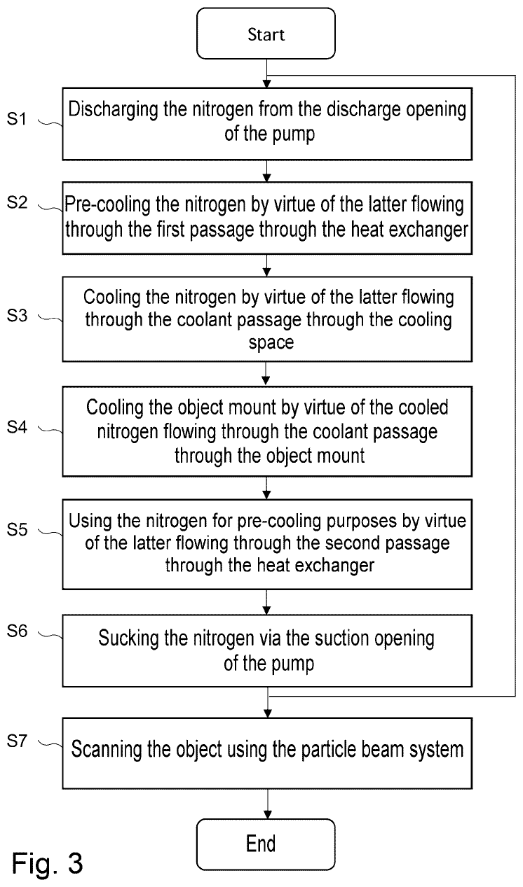

FIG. 3 shows a flowchart for explaining a method for operating the particle beam systems shown in FIGS. 1 and 2.

FIG. 1 shows a particle beam system 1 having a cooling system 3 according to one embodiment. The particle beam system 1 comprises a particle beam source 5 which is connected to a controller 9 via an electrical line 7. The controller 9 is capable of supplying a first electric potential to the particle beam source 5 via the electrical line 7. The particle beam system 1 further comprises a beam tube 11 having an upper end 13 and a lower end 15. The beam tube 11 is connected to the controller 9 via an electrical line 17. By way of the electrical line 17, the controller 9 is capable of supplying a second electric potential to the beam tube 11. During an operation of the particle beam system 1, the controller 9 supplies the first electric potential to the particle beam source 5, whereby particles are released from the particle beam source 5. Moreover, the controller 9 supplies the beam tube 11 with a second electric potential that differs from the first electric potential such that the particles released from the particle beam source 5 are accelerated towards the upper end 13 of the beam tube 11 and form a particle beam 19.

It should be observed that the upper end 13 of the beam tube 11 acts like an acceleration electrode in the example described herein. However, provision can be made for an additional acceleration electrode which may be comprised in the particle beam source 5, for example, in the particle beam system 1 shown in FIG. 1.

The particle beam 19 passes through a condenser lens 21 which comprises a pole shoe 25 and a coil 23. The coil 23 of the condenser lens 21 is connected to the controller 9 via an electrical line 27, with the result that this controller is capable of supplying an electric current to the coil 23 of the condenser lens 21, whereby the coil 23 of the condenser lens 21 creates a magnetic field. The magnetic field created by the coil 23 of the condenser lens 21 enters the beam tube 11 at an opening of the pole shoe 25 and influences the particle beam 19 passing through the condenser lens 21. The condenser lens 21 is used to collimate the particle beam 19. However, the condenser lens 21 can also be used to focus the particle beam 19. Even though the condenser lens 21 is depicted as a magnetic lens in FIG. 1, the condenser lens 21 might also be any other lens suitable for influencing the particle beam 19. For example, the condenser lens can be an electrostatic lens, such as a single lens.

The particle beam 19 furthermore passes through an objective lens 29 which comprises a coil 31 and a pole shoe 33 with a lower end 35. The coil 31 of the objective lens 29 is connected to the controller 9 via an electrical line 37, with the result that this controller is capable of supplying an electric current to the coil 31 of the objective lens 29, whereby the coil 31 of the objective lens 29 creates a magnetic field. The pole shoe 33 of the objective lens 29 has a lower end 35, which is arranged below the lower end 15 of the beam tube 11. The pole shoe 35 of the objective lens 29 is open towards the particle beam 19, with the result that the magnetic field created by the coil 31 of the objective lens 29 is able to enter the pathway of the particle beam 19 in order to influence the letter.

The particle beam 19 is focused on an object 39 by the objective lens 29. It should be observed that focusing of the particle beam 19 can also be performed by the condenser lens 21. Moreover, in a manner similar to the condenser lens 21, the objective lens 29 can also be an electrostatic lens, for example a single lens, rather than the magnetic lens shown in FIG. 1.

The particle beam 19 also passes through an electrostatic lens which is formed by the lower end 15 of the beam tube 11 and the object 39. Via an electrical line 41 and an object mount 43, a third potential can be supplied to the object 39 by the controller 9. In the particle beam system 1 described herein, it is desirable for the third electric potential supplied to the object 39 to correspond to a zero potential in order to avoid an energy supply by the controller 9.

An electric field between the lower end 15 of the beam tube 11 and the object 39 is defined by a difference between the second electric potential supplied to the beam tube 11 and the third electric potential supplied to the object 39. The particle beam 19 is influenced when passing through this electric field prevalent between the lower end 15 of the beam tube 11 and the object 39. This electric field creates an effect of a focusing lens. This structure can also be referred to as a combination of lens since there is a significant overlap between the electric field of the electrostatic lens and the magnetic field of the objective lens 29.

An incidence location of the particle beam 19 on the object 39 is influenced by a deflection arrangement 45. In the example shown in FIG. 1, the deflection arrangement 45 comprises a plurality of pairs of electrodes which create an electric field that deflects the particle beam 19 passing through the electric field when, via an electrical line 47, a voltage is supplied between the electrodes of a pair by the controller 9.

When the particle beam 19 is incident on the object 39, the object 39 emits electrons which are accelerated into the beam tube 11 on account of the focusing electrostatic lens between the object 39 and the lower end 15 of the beam tube 11. The beam tube 11 also comprises a space 49 for components, in which, as shown in FIG. 1, a detector 51, for example, is arranged, the latter being connected to the controller 9 via an electrical line 53. The detector 51 comprises a detector area for detecting the electrons entering into the beam tube 11. The detector 51 creates a detector signal which represents a total number of electrons incident on the detector 51 and transmits the detector signal to the controller 9 via the electrical line 53.

The particle beam system 1 creates an image of the object 39 by virtue of the controller 9 setting different voltage values at the deflection arrangement 45 and assigning each of these voltage values to a detector signal. To this end, the detector signals and the voltage values can be stored in a memory of the controller 9.

The particle beam system 1 further comprises an object stage 55. The object stage 55 can be moved by an actuator 57, wherein the actuator 57 can be activated by the controller 9 via an electrical line 59. For example, a distance between the lower end 35 of the pole shoe 33 of the object lens 29 and the object 39, which can also be referred to as the working distance, can be changed by way of the actuator 57.

The object stage 55 carries the object mount 43 at a distance which is defined by spacers 61 between the object stage 55 and the object mount 43. As shown in FIG. 1, the spacers 61 might have a spherical form in order to keep a contact area between the object mount 43 and the spacers 61, or between the object stage 55 and the spacers 61, as small as possible. Reducing this contact area reduces the heat transfer between the object stage 55 and the object mount 43 to be cooled.

The particle beam system 1 further comprises a vacuum cladding 63 which surrounds a vacuum chamber 65 in which the above-described components of the particle beam system 1, with the exception of the controller 9, are arranged. Air is sucked out of the vacuum chamber 65 using a pump (not shown) connected to a pump nozzle 67, and hence a vacuum is created.

The particle beam system 1 further comprises the cooling system 3. The cooling system 3 comprises a coolant passage 69 through the object mount 43. The object mount 43 can dissipate heat to a coolant by way of the coolant passage 69. The coolant used to this end is a gas, for example nitrogen. For the above-described purpose, the coolant passage 69 comprises an inlet port 71, in which the nitrogen flows into the coolant passage 69 during a cooling operation, and an outlet port 73, from which the nitrogen flows out of the coolant passage 69 during the cooling operation.

The inlet port 71 of the coolant passage 69 is connected to a heat exchanger 74 via a first coolant line 75. To this end, a first end of the coolant line 75 is connected to the input port 71 of the coolant passage 69, the coolant line 75 is guided out of the vacuum chamber 65 through a vacuum seal 79 through the vacuum cladding 63 and a second end of the coolant line 75 is connected to a first passage 78 through the heat exchanger 74. The vacuum seal 79 is a seal which hermetically closes off an opening in the vacuum cladding 63. For example, the vacuum seal 79 is a rubber seal or a metal seal. For example, the vacuum seal 79 shown in FIG. 1 is a double feedthrough which in addition to the first coolant line 75 also guides a second coolant line 81 out of the vacuum chamber 65 through the vacuum cladding 63. The second coolant line 81 is connected at a first end to the outlet port 73 of the coolant passage 69 and connected at a second end to a second passage 76 through the heat exchanger 74.

The cooling system 3 moreover comprises a further vacuum cladding 91 which surrounds a portion of the first coolant line 75, the second coolant line 81 and the heat exchanger 74. The vacuum cladding 91 comprises a pump nozzle 92, connected to which is a further pump (not shown) which when the pump is operated pumps air out of a vacuum chamber 94 surrounded by the vacuum cladding 91, whereby a vacuum is created in the vacuum chamber 94. The vacuum chamber 94 acts as a thermally insulating layer for a portion of the first coolant line 75, the second coolant line 81 and the heat exchanger 74. For example, the vacuum prevalent in the vacuum chamber 94 reduces a heat transfer between the components of the cooling system 3 surrounded by the vacuum cladding 91 and the surroundings. Moreover, the vacuum prevalent in the vacuum chamber 94 prevents an icing over of water suspended in the surroundings at the first coolant line 75, the second coolant line 81 and the heat exchanger 74. It should be observed that the vacuum chamber 94 might be connected to the vacuum chamber 65 such that the vacuum in the vacuum chamber 94 can be created by the pump (not shown) at the pump nozzle 67. The pump nozzle 92 is not required in this case.

The cooling system 3 also comprises a cooling mechanism 83 which has a cooling space 85. Liquid nitrogen 87 is filled into the cooling space 85, for example before the cooling system is put into operation, and the coolant passage 89 of the cooling mechanism 83 is submersed in the liquid nitrogen 87. For example, the coolant passage 89 in this case is a portion of the first coolant line 75 which is led out of the vacuum chamber 94 via vacuum seals 80 through the vacuum cladding 91. The nitrogen flowing through the coolant passage 89 through the cooling mechanism 83 is cooled by the liquid nitrogen 87. It should be observed that a portion of the vacuum cladding 91 can be designed as a flexible tube through which the first coolant line 75 and the second coolant line 81 are guided, and at the end of which the coolant passage 89 through the cooling mechanism 83 is attached. Such a flexible tube offers a simple option for submersing the coolant passage 89 through the cooling mechanism 83 in the liquid nitrogen 87 before the start of the cooling operation of the cooling mechanism 83. For example, such a flexible tube is a corrugated tube.

The heat exchanger 74 comprises the first passage 78 and the second passage 76 and is a countercurrent heat exchanger, in which the nitrogen flows in opposite directions through the first passage 78 and the second passage 76. The heat exchanger 74 is also connected to a third coolant line 108 and a fourth coolant line 110. The third coolant line 108 and the fourth coolant line 110 are each guided out of the vacuum chamber 94 through a vacuum seal 82. The third coolant line 108 is connected to a discharge opening 124 of a pump 120, and the fourth coolant line 110 is connected to a suction opening 122 of the pump 120, with the result that the cooling system 3 forms a closed circuit.

The heat exchanger 74 enables an efficient heat transfer between the nitrogen In the first passage 78 through the heat exchanger 74 and the nitrogen in the second passage 76 through the heat exchanger 74. Even though the heat exchanger 74 in FIG. 1 is depicted as a simple countercurrent heat exchanger, use can be made of any heat exchanger that is suitable for the present purposes. For example, use can be made of a heat exchanger in which the first passage 78 and the second passage 76 are in the form of two concentric tubes such that the second passage 76 surrounds the first passage 78. What the heat exchanger 74 achieves is that the nitrogen in the first passage 78 through the heat exchanger 74 is pre-cooled by the nitrogen in the second passage 76 through the heat exchanger 74 before the nitrogen is cooled in the coolant passage 89 through the cooling mechanism 83. The upshot of the pre-cooling of the nitrogen in the first passage 78 through the heat exchanger 74 is that a consumption of the liquid nitrogen 87 in the cooling mechanism 83 is reduced since the liquid nitrogen 87 absorbs less heat from the nitrogen, and hence evaporates in a smaller quantity. This further reduces nitrogen consumption.

The pump 120 is connected via an electrical line 128 to a controller 103 such that the pump 120 can be operated and, for example, the pump 120 can be operated at a specific delivery rate. For example, the pump 120 is a fan which is able to create a flow of nitrogen by the rotation of fan blades (not shown). For example, the pump 120 creates a flow of nitrogen in a direction indicated in FIG. 1 by an arrow 126 in the symbol of the pump 120, and by the arrows 112. That is to say the pump 120 takes up the nitrogen via the suction opening 122 and discharges the nitrogen via the discharge opening 124, whereby a nitrogen flow is created.

A reducing valve 99 is provided in the third coolant line 108 in order to be able to set a nitrogen flow independently of the delivery rate of the pump 120. For example, the reducing valve 99 is a magnetic valve, which can be controlled electrically. To this end, the reducing valve 99 is connected to the controller 103 via an electrical line 101. For example, the controller 103 determines an electric current that should be supplied to a magnetic valve in order to attain a specific flow of the nitrogen and feeds the electric current to the reducing valve 99.

The cooling system 3 also comprises two compensation containers 130 which are connected via ports 132 to the third coolant line 108 and the fourth coolant line 110, respectively. The compensation containers 130 shown in FIG. 1 have an elastic sleeve which expands or contracts depending on a nitrogen pressure prevalent in the third coolant line 108 or in the fourth coolant line 110. This is shown by the arrows depicted within the compensation containers 130 in FIG. 1. The compensation containers 130 provide a variable volume for this reason. When a cooling operation of the cooling system 3 is started, a portion of the nitrogen flowing through the coolant passage 89 through the cooling mechanism 83, through the portion of the first coolant line 75 between the cooling mechanism 83 and the coolant passage 69 through the object mount 43 and through the coolant passage 69 through the object mount 43 is cooled. The cooling results in a compression of this nitrogen and thus reduces a nitrogen pressure in the cooling system 3. The provided volume of the compensation containers 130 consequently reduces, whereby the change in the pressure of the nitrogen in the cooling system 3 can be reduced and damage to the cooling system 3 can be prevented.

The compensation container 130 connected to the third coolant line 108 additionally comprises a pressure sensor 134 which is connected to the controller 103 via an electrical line 136. For example, the pressure sensor 134 is a piezoelectric sensor. From the pressure sensor 134, the controller 103 receives a signal via the electrical line 136, the signal representing a pressure in the compensation container 130 connected to the third coolant line. For example, the controller 103 compares the signal received by the pressure sensor 134 with a predetermined value and changes the delivery rate of the pump 120 via the electrical line 128 such that the received signal corresponds to the predetermined value. For example, such feedback control of the pump 120 allows a compensation of a change in pressure in the cooling system 3 that cannot be compensated for by the compensation containers 130. Hence damage to the cooling system 3 can be prevented.

The cooling system 3 also comprises a nitrogen reservoir 97 that is connected to the third coolant line 108 via a supply port 95. The supply port 95 comprises a pressure valve 138 which opens when a pressure within the third coolant line 108 is lower than a reference pressure that can be set at the pressure valve 138. Alternatively, the pressure valve 138 can also be connected to the controller 103 via a further electrical line, and a further pressure sensor can be provided to implement the aforementioned function of the pressure valve 138. The nitrogen reservoir 97 serves to fill the cooling system with nitrogen before the cooling system 3 is put into operation but can also be used to compensate for a change in pressure within the cooling system 3. When the pressure within the cooling system 3 is reduced within the scope of cooling the nitrogen, the pressure within the third coolant line 108 drops below the reference pressure set at the pressure valve 138, whereby more nitrogen is fed from the nitrogen reservoir 97 to the third coolant line 108 until the pressure within the third coolant line 108 is greater than or equal to the reference pressure set at the pressure valve 138. It should be observed that only the compensation containers 130 or the pressure valve 138 are used for compensating the change in pressure within the cooling system 3 that arises during the cooling process; however, both the compensation containers 130 and the pressure valve 138 can be used.

If the supply port 95 and for example the pressure valve 138 are operated in the manner described above for the purpose of compensating the change in pressure within the cooling system 3 that arises during the cooling process, then use is made of a relief valve 140 which opens when a pressure in the fourth coolant line 140 exceeds a reference pressure set at the relief valve 140. The opened relief valve 140 releases nitrogen to the surroundings. This is desirable when operating the supply port 95 for the purpose of compensating a change in pressure since additional nitrogen is fed during the cooling process. Once the cooling operation of the cooling system 3 is terminated, the nitrogen expands during the subsequent heating, and this leads to an increase of pressure in the cooling system 3. The relief valve 140 causes nitrogen to be released to the surroundings such that the pressure within the cooling system 3 does not exceed the reference pressure. Hence damage to the cooling system 3 can be prevented.

The above-described particle beam system 1 allows the object to be cooled, with nitrogen consumption of the cooling system being reduced. For example, this object is achieved by virtue of the pump 120 and the compensation containers 130 enabling a closed cooling circuit, from which only a little nitrogen, or none at all, escapes. Moreover, the heat exchanger 74 is used to reduce a consumption of the liquid nitrogen 87, as described above.

FIG. 2 shows the particle beam system 1 having the cooling system 3 according to a further embodiment. This embodiment differs from the above-described embodiment in the type of compensation containers used. Accordingly, a redundant description of other components, which do not relate to the compensation containers 142, is omitted.

The compensation containers 142 are rigid containers which do not change the volume provided by the compensation containers 142 but provide a passage for the nitrogen. That is to say the nitrogen flows through the compensation containers 142 in the case shown in FIG. 2. The compensation containers 142 have a volume that is significantly larger than the volume of the cooled sections of the cooling system 3, for example the volume of the coolant passage 89 through the cooling mechanism 83, plus the volume of the portion of the first coolant line 75 connecting the coolant passage 89 through the cooling mechanism 83 to the coolant passage 69 through the object mount 43, plus the volume of the coolant passage 69 through the object mount 43. For example, the overall volume of the compensation containers 142 is larger than 1000-times the aforementioned sum of these volumes. If the nitrogen is compressed at a start of the cooling operation of the cooling system 3, then a pressure change in the entire cooling system 3 is small on account of the large volume of the compensation containers 142. As described above, a residual change in pressure can be detected by the pressure sensor 134 and can be eliminated by controlling the delivery rate of the pump 120.

FIG. 3 shows a flowchart for explaining a method for operating the particle beam systems 1 shown in FIGS. 1 and 2. The method comprises steps SI to S7. In step S1, the nitrogen is discharged from the discharge opening 124 of the pump 120, whereby the pump 120 creates a flow of nitrogen. Subsequently, in step S2, the nitrogen flows through the first passage 78 through the heat exchanger 74 and is pre-cooled there by virtue of the nitrogen in the first passage 78 through the heat exchanger 74 exchanging heat with the nitrogen in the second passage 76 through the heat exchanger 74. Thereupon, the pre-cooled nitrogen flows through the coolant passage 89 through the cooling mechanism 83 in step S3. In this case, the cooling space 85 of the cooling mechanism 83 is filled with liquid nitrogen 87, and so the nitrogen flowing through the coolant passage 89 through the cooling mechanism 83 is cooled. Then, in step S4, the object mount 43 and the object 39 mounted thereon are cooled by virtue of the nitrogen, which was cooled in step S3, flowing through the coolant passage 69 through the object mount 43.

The nitrogen emerging from the coolant passage 69 through the object mount 43 flows through the second passage 76 through the heat exchanger 74 in step S5, whereby the heat exchanger absorbs heat from the nitrogen in the first passage 78 through the heat exchanger 74 and thus pre-cools the nitrogen in the first passage 78 through the heat exchanger 74. After emerging from the second passage 76 through the heat exchanger 74, the nitrogen is sucked into the pump 120 via the suction opening 122.

Steps S1 to S6 of the method shown in FIG. 3 are carried out repeatedly, to be precise for as long as the object mount 43 and the object 39 mounted thereon should be cooled. It should be observed that steps S1 to S6 are repeated at least until the object mount 43 has reached the desired temperature. For example, this can be determined by way of the temperature sensor 116. Once the desired temperature has been reached, the method shown in FIG. 3 can proceed with step S7. A region on the object 39 is scanned using the particle beam 19 of the particle beam system 1 in step S7. To this end, the controller 9 of the particle beam system 1 supplies the deflection apparatus 45 with different voltages, whereby the particle beam 1 is directed at different incidence locations on the object 39. The controller 9 then creates a particle-optical image from the signals captured by the detector 55. It should be observed that the controller 9 can be connected to the controller 103 via a communications line not shown in FIGS. 1 and 2, with the result that the controller 103 can transmit e.g. the temperature detected by the temperature sensor 116 to the controller 9, or can clear a scanning of the object 39 with the particle beam 19 by the controller 9. Even though the controller 103 and the controller 9 are shown as separate controllers in FIGS. 1 and 2, they can also be designed as a single controller, for example by way of a computer connected to the components to be controlled.

What is claimed is:

1. A particle beam system, comprising:
an object mount configured to mount an object, the object mount comprising a coolant passage;
a particle beam source configured to create a particle beam;
a lens configured to focus the particle beam on the object;
a detector configured to detect signals created by the interaction of the particle beam and the object;
a cooling system in fluid communication with the coolant passage of the object mount to allow a flow of a coolant through the coolant passage of the object mount; and
a controller,
wherein the cooling system comprises:
a cooling mechanism comprising a coolant passage, the cooling mechanism configured to cool coolant in the coolant passage of the cooling mechanism; and
a pump configured to convey the coolant to create the flow of the coolant.

2. The particle beam system of claim 1, wherein the pump is along the flow of the coolant between the object mount and the cooling mechanism.

3. The particle beam system of claim 1, further comprising a coolant line connecting the coolant passage of the cooling mechanism to the coolant passage of the object mount, wherein the cooling system has a coolant-containing maximum volume that is at least 1,000 times larger than a sum of: a volume of the coolant passage through the object mount; a volume of the coolant passage through the cooling mechanism; and a volume of the coolant line.

4. The particle beam system of claim 3, wherein:
the cooling system further comprises at least one compensation container;
a maximum overall volume of the at least one compensation container is 1000-times larger than the sum of: the volume of the coolant passage through the object mount;
the volume of the coolant passage through the cooling mechanism; and the volume of the coolant line.

5. The particle beam system of claim 4, wherein a compensation container comprises an inlet opening for the coolant and an outlet opening for the coolant to provide a passage for the coolant between the inlet opening and the outlet opening.

6. The particle beam system of claim 5, wherein the compensation container is along the flow of the coolant between the object mount and the pump.

7. The particle beam system of claim 4, wherein a compensation container provides a variable volume for the coolant.

8. The particle beam system of claim 1, wherein the cooling system further comprises:
a reducing valve along the flow of the coolant to provide a variable resistance to the flow of the coolant through the reducing valve; and
a temperature sensor configured to output a signal representing a temperature of the object mount, and
wherein the controller is configured to control the reducing valve based on the signal representing the temperature of the object mount.

9. The particle beam system of claim 1, wherein the cooling system further comprises a pressure sensor configured to output a signal representing a pressure of the coolant flowing between the object mount and the cooling mechanism, and the controller is configured to control a delivery rate of the pump based on the signal representing the pressure.

10. The particle beam system of claim 1, further comprising:
a coolant line along the flow of the coolant between the cooling mechanism and the object mount; and
an insulating layer surrounding a portion of the coolant line.

11. The particle beam system of claim 1, wherein the cooling mechanism comprises a cooling space through which the coolant passage of the cooling mechanism, the cooling space configured to accommodate liquid nitrogen.

12. The particle beam system of claim 11, wherein the coolant passage through the cooling mechanism is non-destructively removable from the cooling space and subsequently re-insertable therein.

13. The particle beam system of claim 1, further comprising a vacuum cladding delimiting a vacuum chamber, wherein the object mount is within the vacuum chamber, and the pump is outside the vacuum chamber.

14. The particle beam system of claim 13, wherein the cooling mechanism is outside the vacuum chamber.

15. The particle beam system of claim 1, wherein the coolant comprises gaseous nitrogen.

16. The particle beam system of claim 1, further comprising an object stage that is displaceable relative to the lens, wherein the object stage carries the object mount.

17. The particle beam system of claim 16, wherein the object mount is thermally insulated from the object stage.

18. The particle beam system of claim 17, wherein:
the object mount comprises a main face facing the object stage;
the object stage comprises a main face facing the object mount; and
the particle beam system comprises less than 10 spacers between the object mount and the object stage to maintain a distance between the main face of the object mount and the main face of the object stage.

19. The particle beam system of claim 1, wherein:
the cooling system further comprises a heat exchanger comprising first and second passages;
the first passage through the heat exchanger is along the flow of the coolant between the cooling mechanism and the pump; and
the second passage through the heat exchanger is along the flow of the coolant between the pump and the object mount.

20. A method, comprising:
operating a particle beam system of claim 19 by a method comprising:
pre-cooling the coolant in the first passage using the heat exchanger;
cooling the coolant in the coolant passage through the cooling mechanism;
using the cooled coolant to cool the object mount and an object arranged on the object mount;
after cooling the object mount, using the coolant in the second passage through the heat exchanger for pre-cooling using the heat exchanger; and
scanning the particle beam over the object and detecting signals using the detector.

21. The method of claim 20, wherein the coolant comprises gaseous nitrogen.

22. One or more machine-readable hardware storage devices comprising instructions that are executable by one or more processing devices to perform operations comprising the method of claim 19.

23. A system comprising:
one or more processing devices; and
one or more machine-readable hardware storage devices comprising instructions that are executable by the one or more processing devices to perform operations comprising the method of claim 19.
